(19) United States
(12) Patent Application Publication
(10) Pub. No.: US 2022/0302141 A1
(43) Pub. Date: Sep. 22, 2022

(54) SEMICONDUCTOR MEMORY DEVICE

(71) Applicant: Kioxia Corporation, Tokyo (JP)

(72) Inventor: Kenji WATANABE, Yokkaichi (JP)

(73) Assignee: Kioxia Corporation, Tokyo (JP)

(21) Appl. No.: 17/473,358

(22) Filed: Sep. 13, 2021

(30) Foreign Application Priority Data
Mar. 19, 2021 (JP) 2021-045788

(51) Int. Cl. H01L 27/1157; H01L 27/11565; H01L 27/11578

(52) U.S. Cl. CPC H01L 27/1157; H01L 27/11565; H01L 27/11578

(57) ABSTRACT

According to one embodiment, a semiconductor memory device includes a stacked layer body in which a plurality of conductive layers are stacked to be apart from each other in a first direction, a plurality of pillar structures each including a semiconductor layer extending in the first direction through the stacked layer body, a plurality of partition structures each of which extends in the first direction and a second direction in the stacked layer body, and which divide the stacked layer body into a plurality of portions in a third direction, and a covering layer which covers the stacked layer body and the partition structures, and in which a height in each of regions covering top surfaces of the partition structures is positioned higher than a height in each of regions covering the portions of the stacked layer body.

### CROSS-REFERENCE TO RELATED APPLICATIONS

This application is based upon and claims the benefit of priority from Japanese Patent Application No. 2021-045788, filed Mar. 19, 2021, the entire contents of which are incorporated herein by reference.

### FIELD

Embodiments described herein relate generally to a semiconductor memory device.

### BACKGROUND

In a three-dimensional nonvolatile memory in which a plurality of memory cells are stacked on a semiconductor substrate, it is important to form contacts in a suitable and appropriate manner.

### BRIEF DESCRIPTION OF THE DRAWINGS

FIG. 1 is a view schematically showing a plane pattern of the basic configuration of a semiconductor memory device according to a first embodiment.

FIG. 2 is a cross-sectional view schematically showing the basic configuration of the semiconductor memory device according to the first embodiment.

Each of FIG. 3A and FIG. 3B is a cross-sectional view schematically showing the detailed configuration of a memory cell part of the semiconductor memory device according to the first embodiment.

Each of FIG. 4A, FIG. 4B, FIG. 4C, FIG. 4D, FIG. 4E, FIG. 4F, FIG. 4G, FIG. 4H, FIG. 4I, FIG. 4J, FIG. 4K, FIG. 4L, and FIG. 4M is a cross-sectional view schematically showing a part of a manufacturing method of the semiconductor memory device according to the first embodiment.

Each of FIG. 5A and FIG. 5B is a cross-sectional view schematically showing a state of a vicinity of a boundary region between the memory cell array region and peripheral circuit region with respect to a manufacturing method of a comparative example of the semiconductor memory device according to the first embodiment.

FIG. 6 is a view showing a problem which can arise when contact holes are formed with respect to the manufacturing method of the comparative example of the semiconductor memory device according to the first embodiment.

Each of FIG. 7A and FIG. 7B is a cross-sectional view schematically showing a state of a vicinity of a boundary region between the memory cell array region and peripheral circuit region with respect to the manufacturing method of the semiconductor memory device according to the first embodiment.

Each of FIG. 8A and FIG. 8B is a cross-sectional view schematically showing a modified example of a state of a vicinity of a boundary region between the memory cell array region and peripheral circuit region with respect to the manufacturing method of the semiconductor memory device according to the first embodiment.

FIG. 9 is a cross-sectional view schematically showing the basic configuration of a semiconductor memory device according to a second embodiment.

Each of FIG. 10A, FIG. 10B, FIG. 10C, FIG. 10D, FIG. 10E, FIG. 10F, FIG. 10G, FIG. 10H, FIG. 10I, and FIG. 10J is a cross-sectional view schematically showing a part of a manufacturing method of the semiconductor memory device according to the second embodiment.

### DETAILED DESCRIPTION

In general, according to one embodiment, a semiconductor memory device includes: a stacked layer body in which a plurality of conductive layers are stacked to be apart from each other in a first direction; a plurality of pillar structures each of which includes a semiconductor layer extending in the first direction through the stacked layer body; a plurality of partition structures each of which extends in the first direction and a second direction intersecting the first direction in the stacked layer body, and which divide the stacked layer body into a plurality of portions in a third direction intersecting the first and second directions; and a covering layer which covers the stacked layer body and the plurality of partition structures, and in which a height in each of regions covering top surfaces of the plurality of partition structures is positioned higher than a height in each of regions covering the portions of the stacked layer body.

Embodiments will be described hereinafter with reference to the accompanying drawings.

### First Embodiment

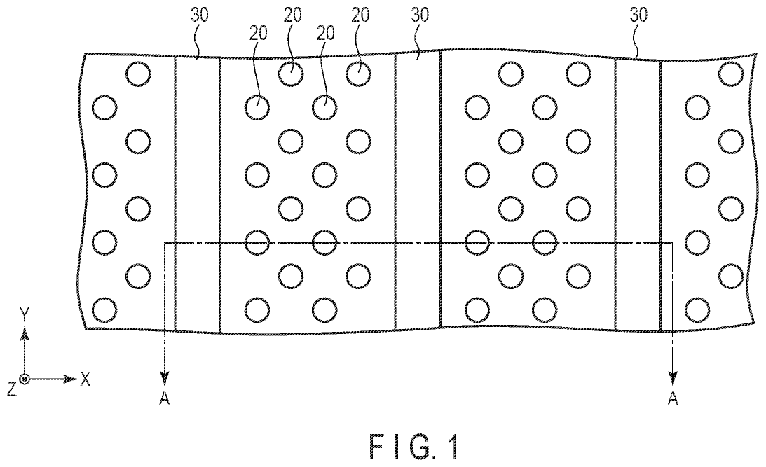

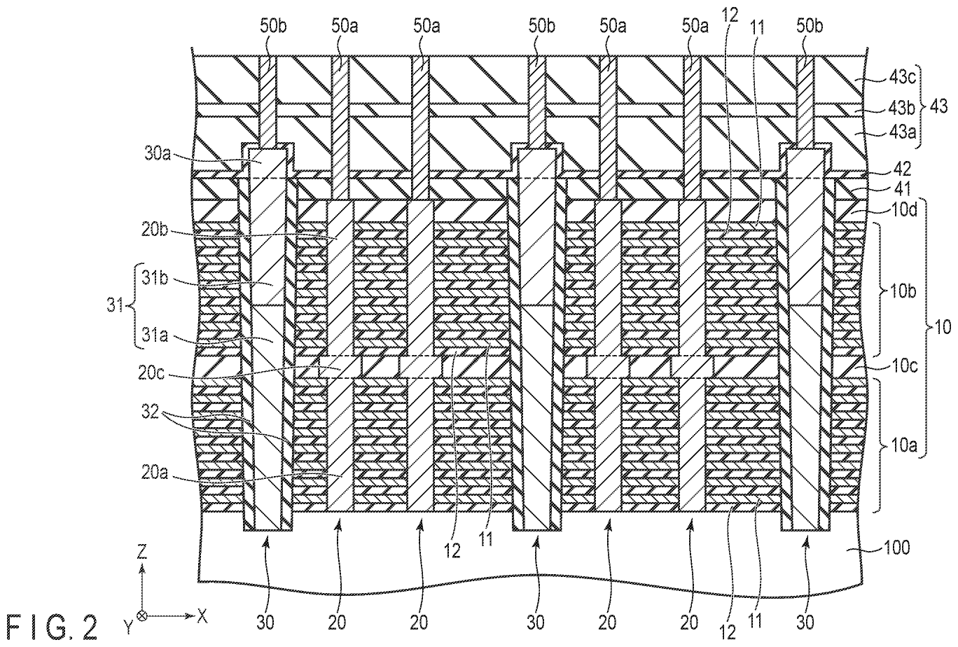

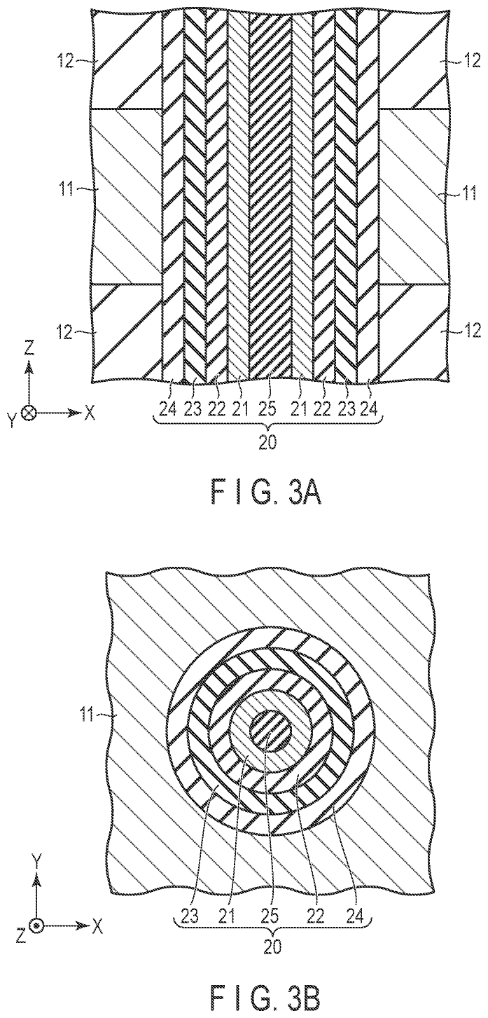

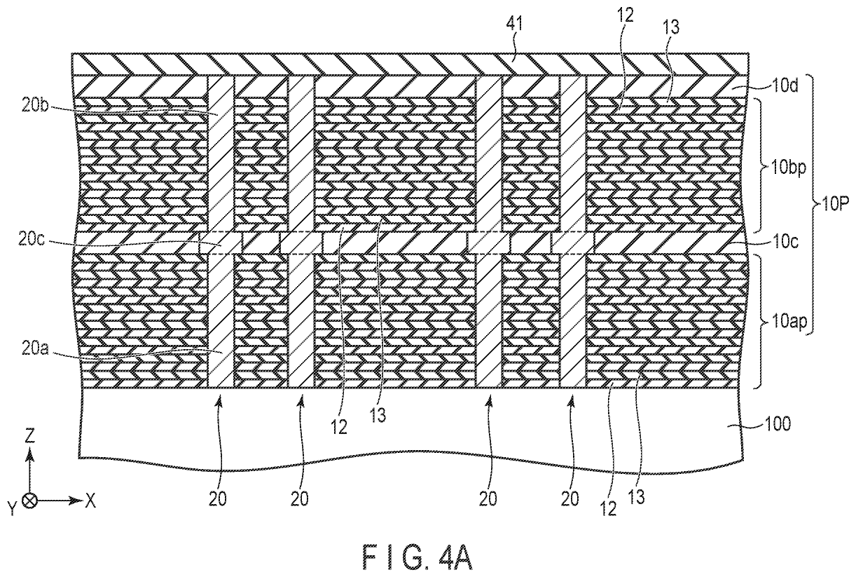

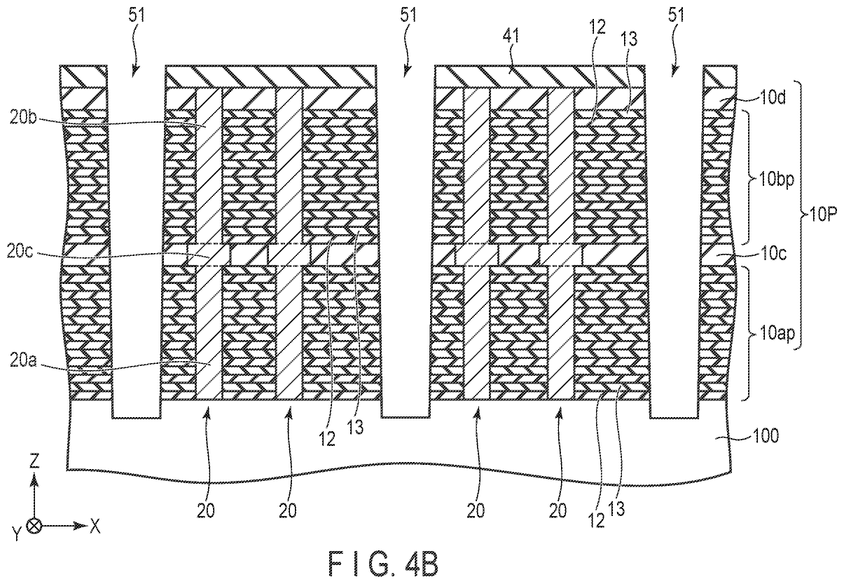

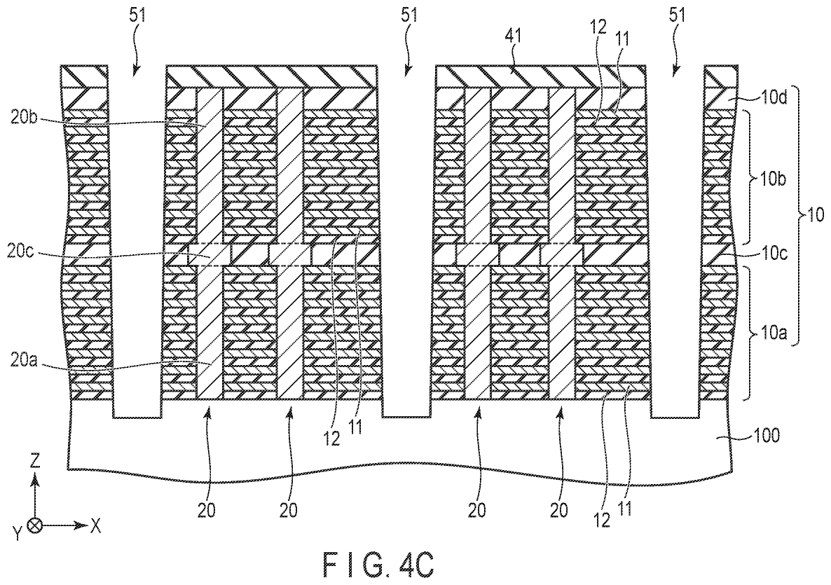

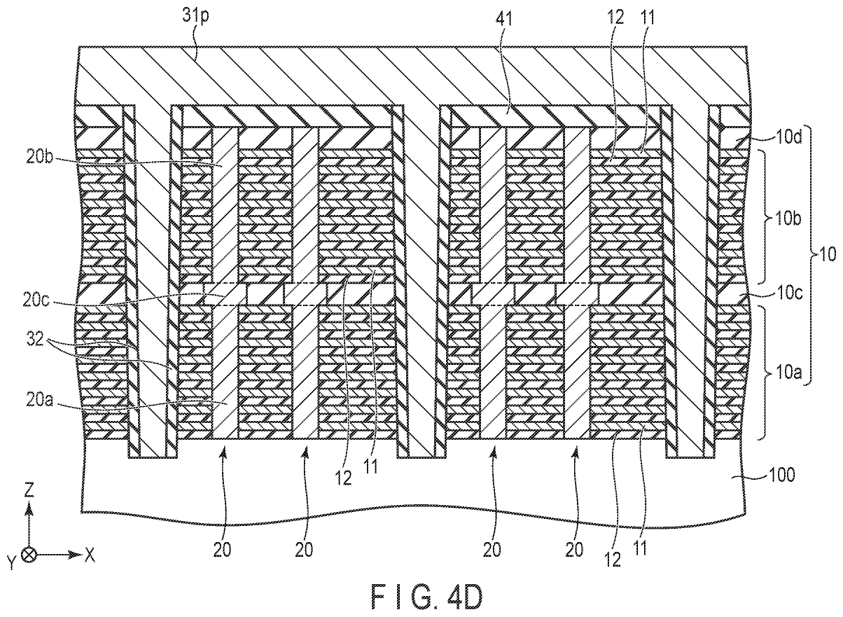

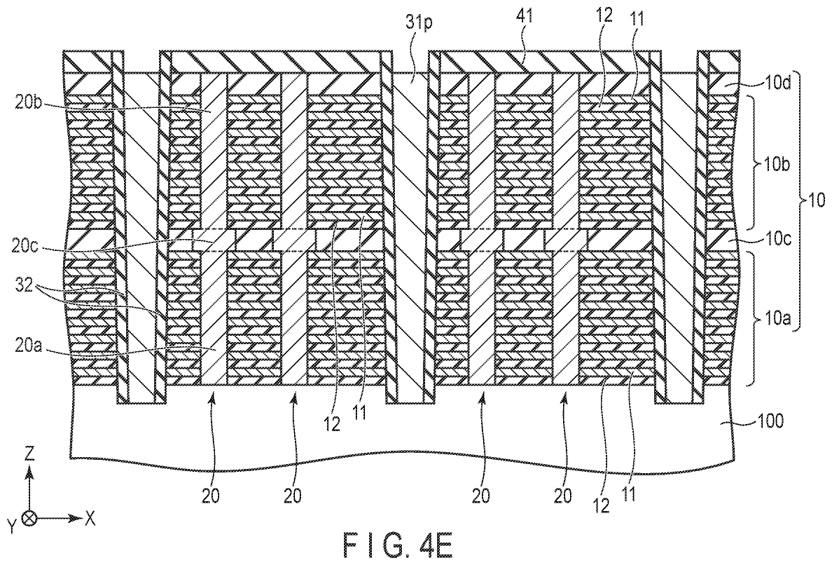

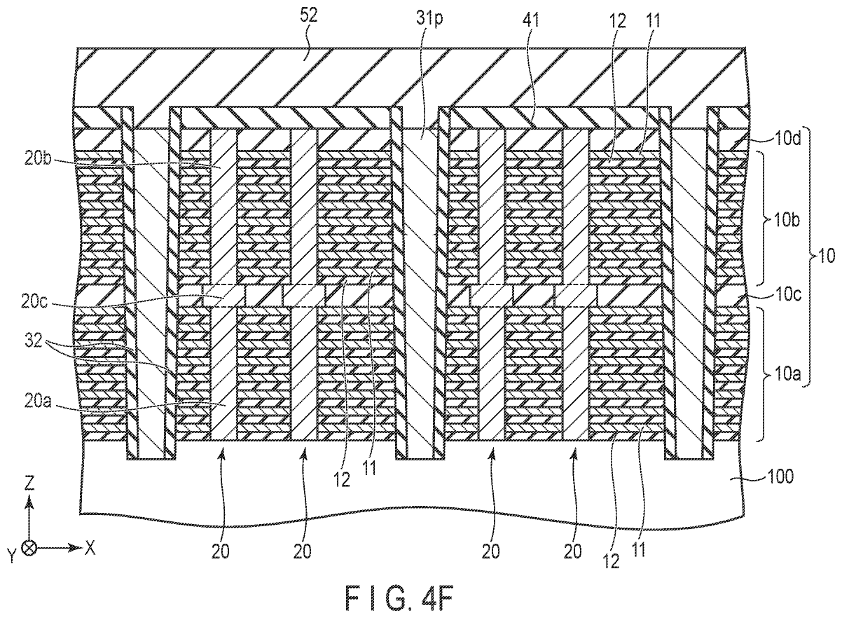

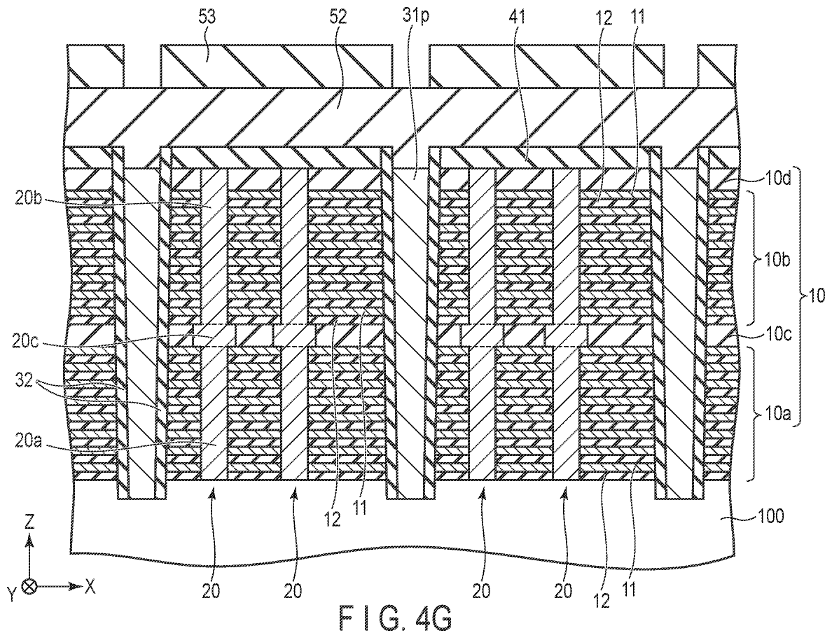

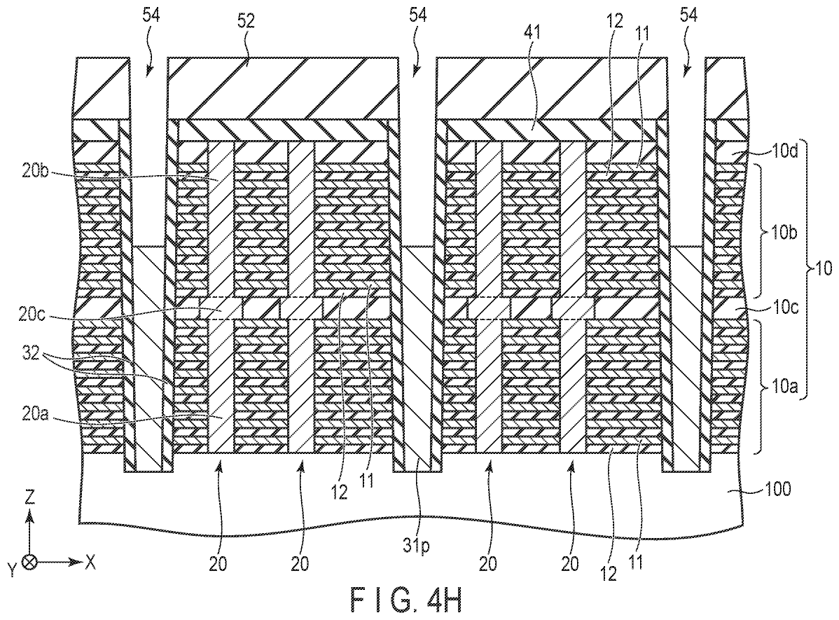

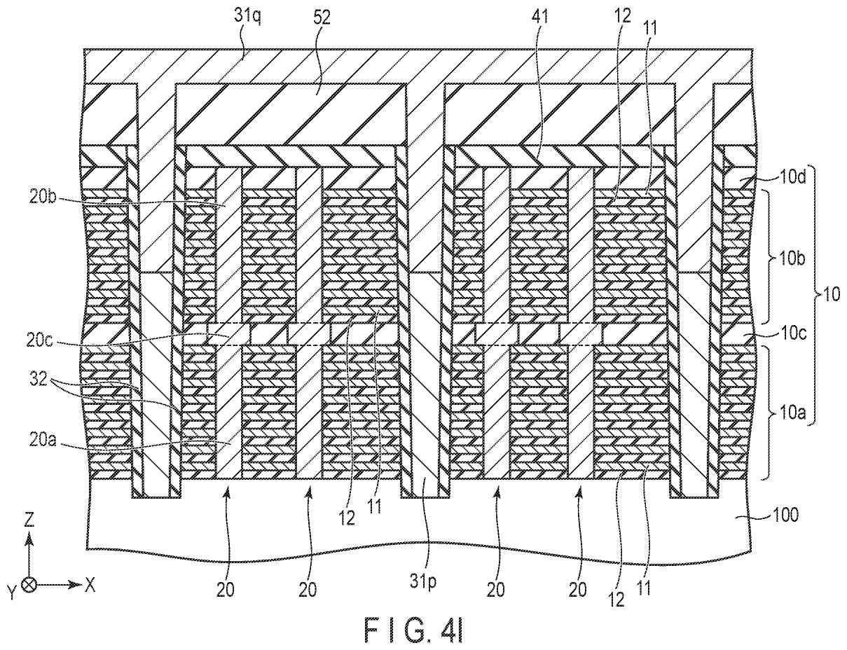

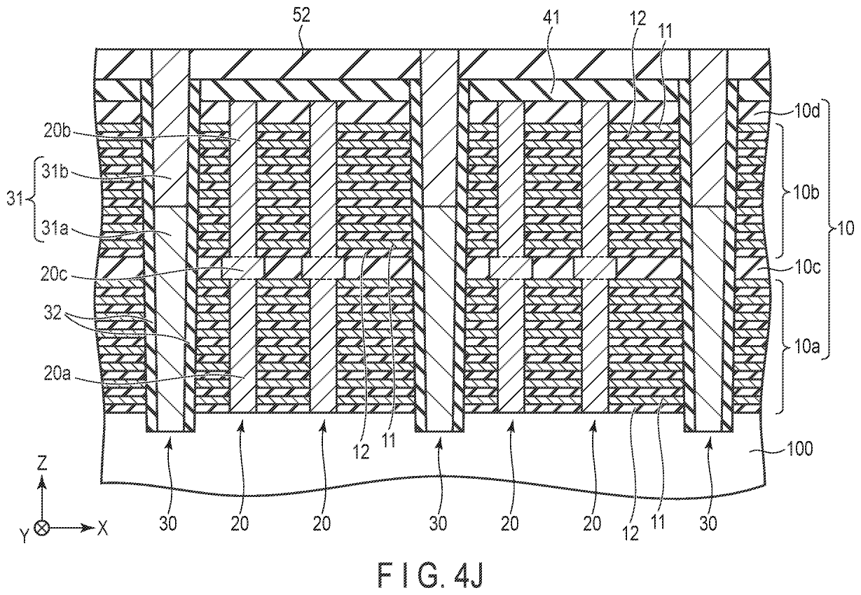

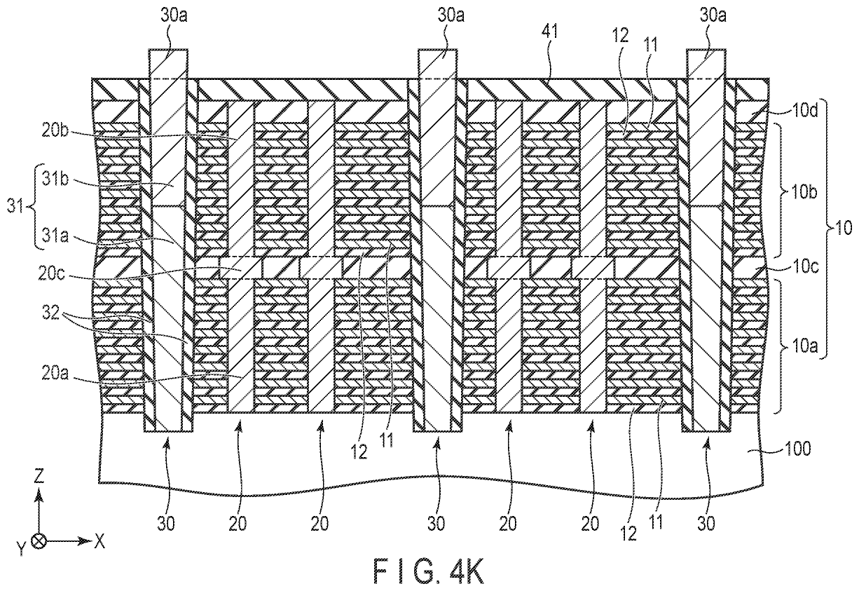

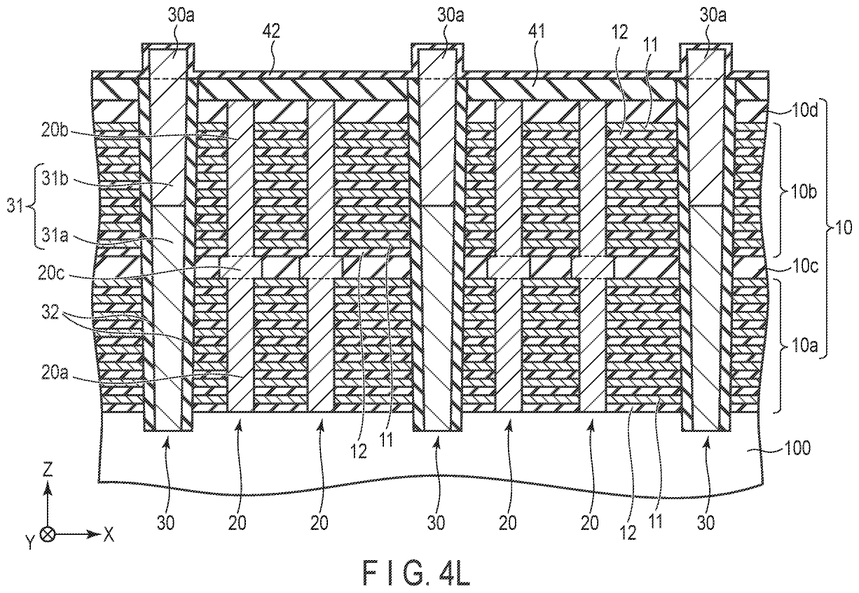

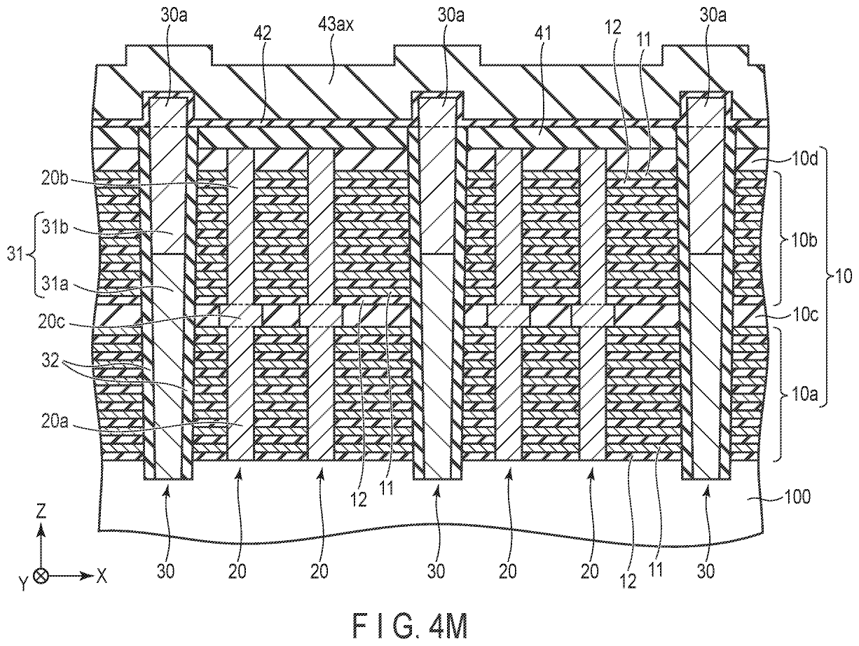

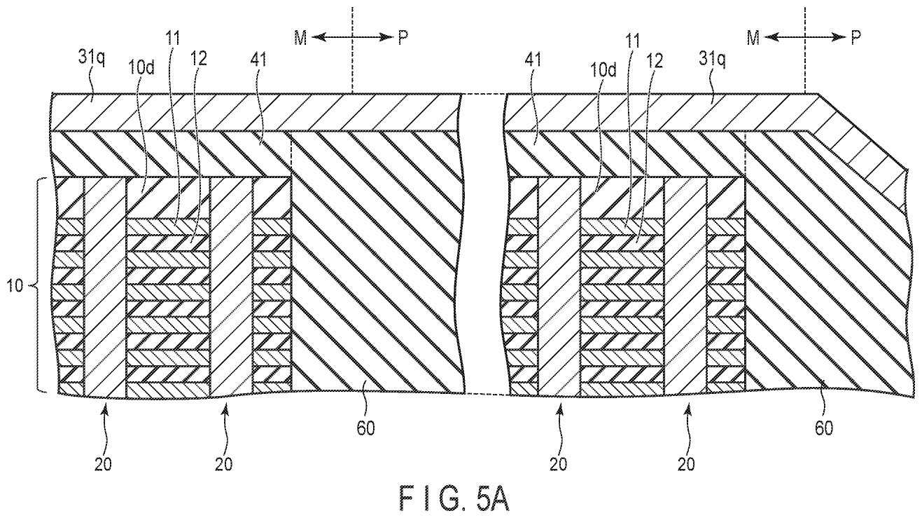

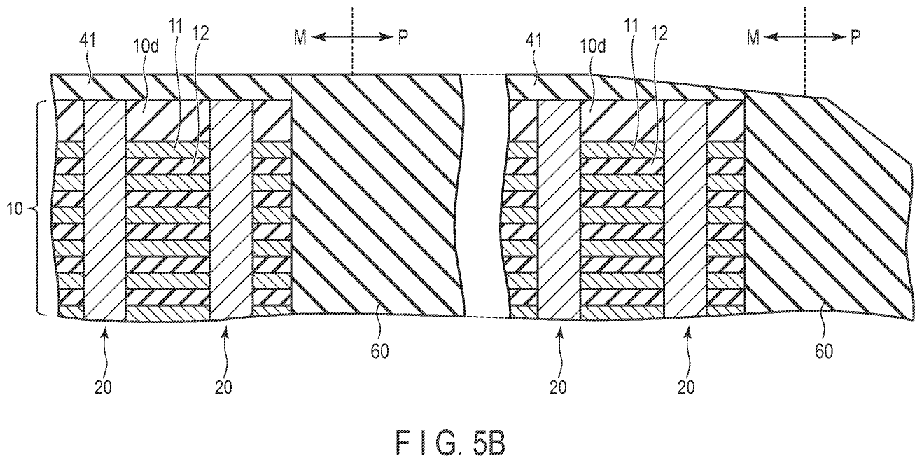

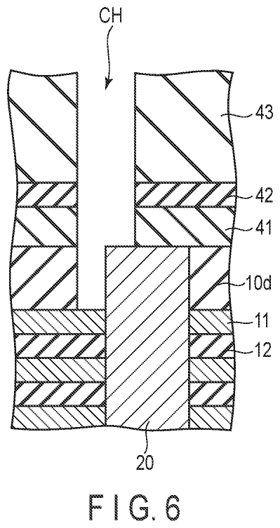

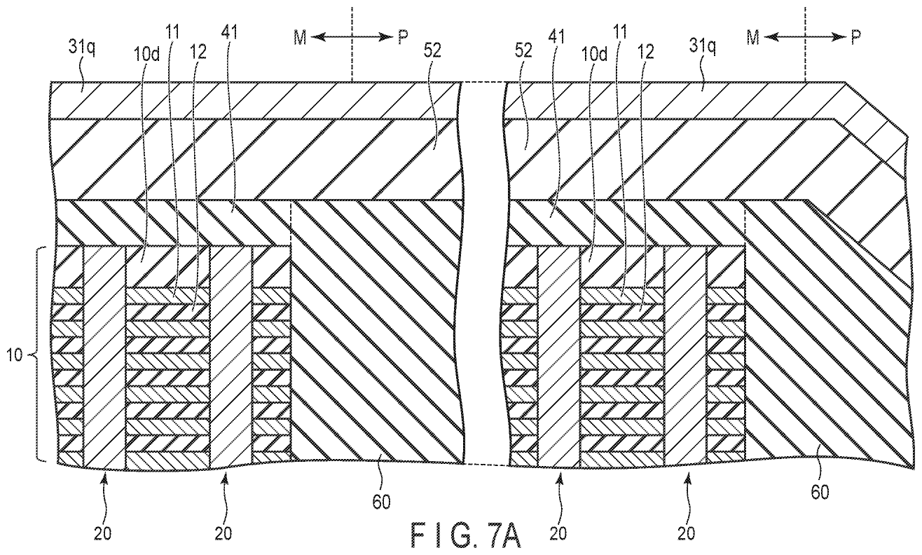

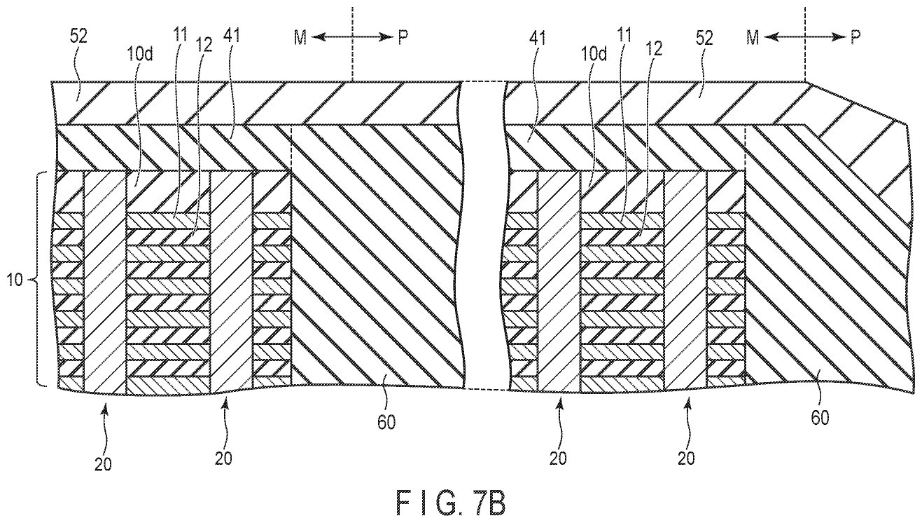

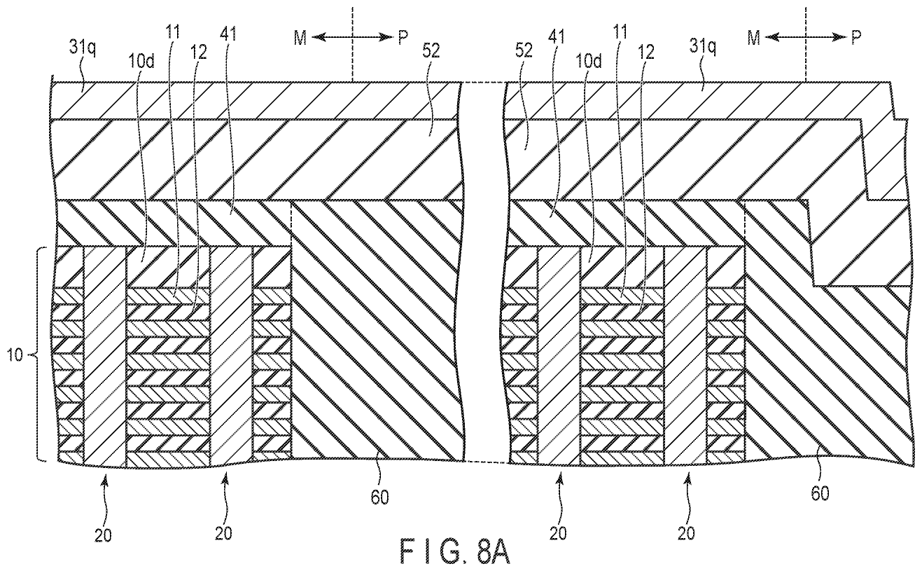

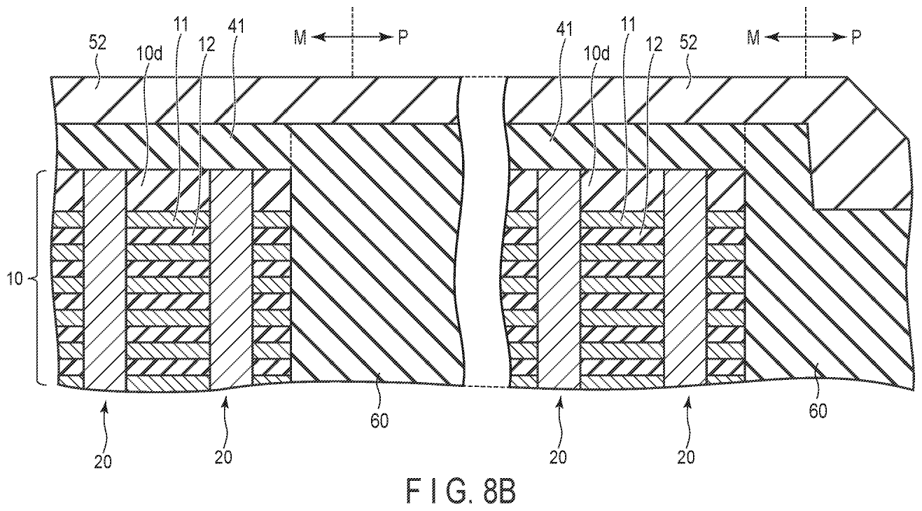

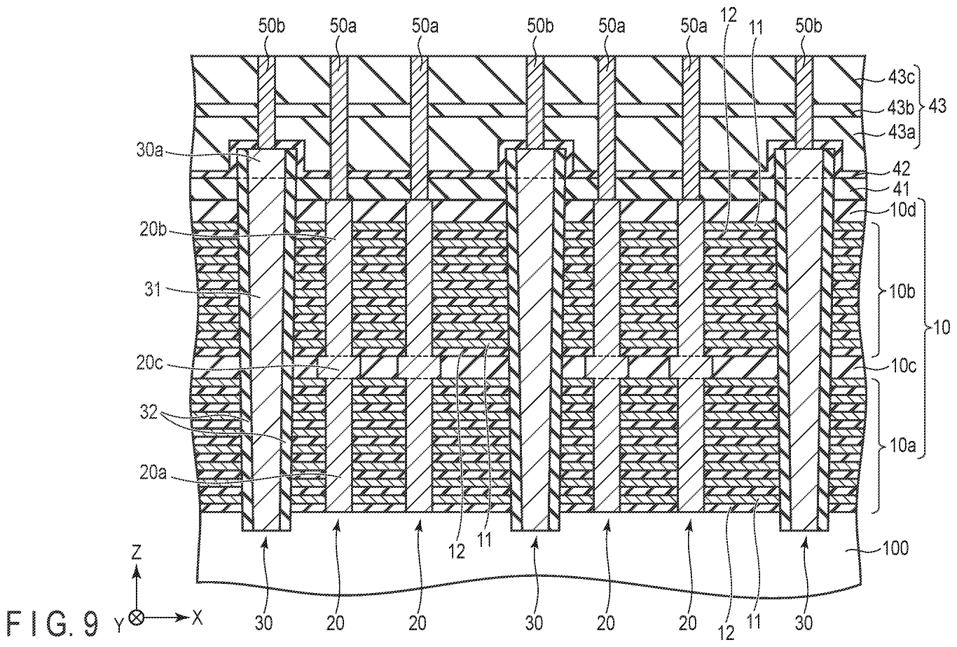

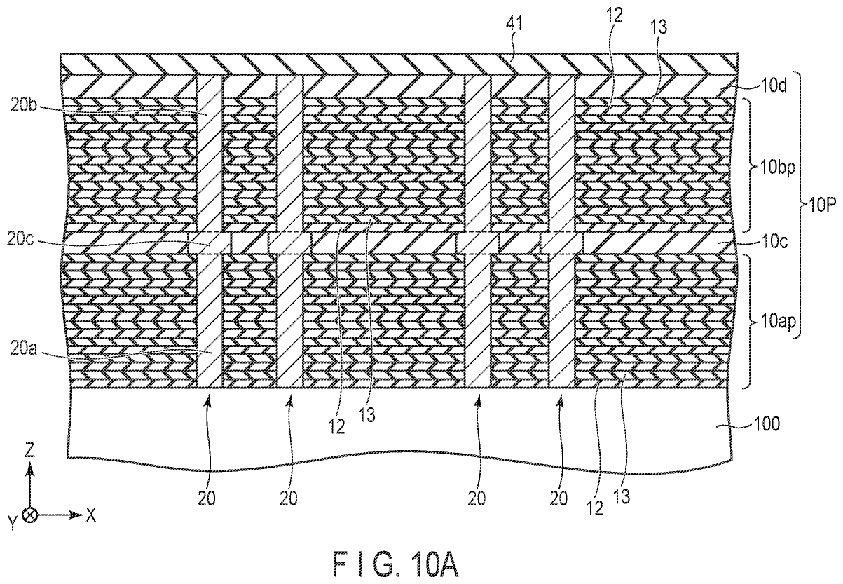

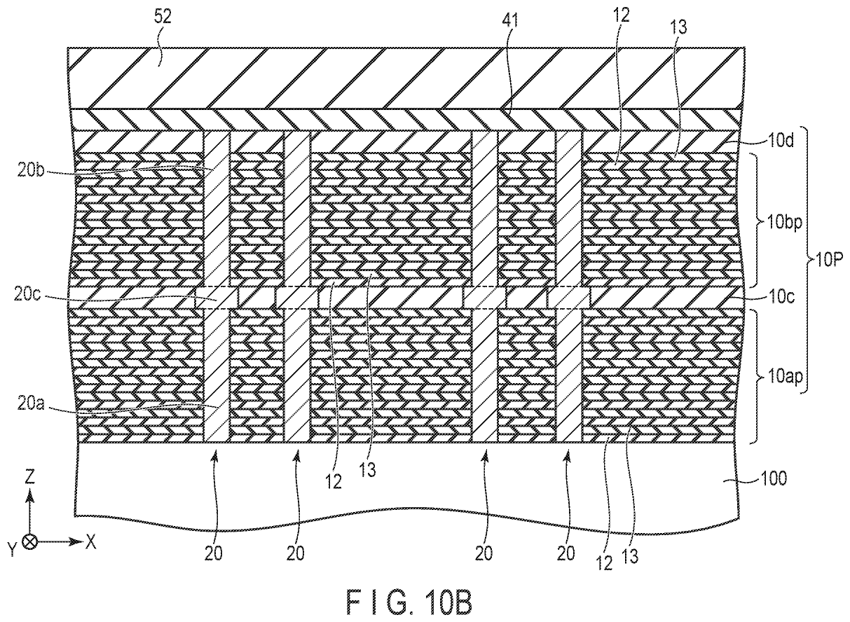

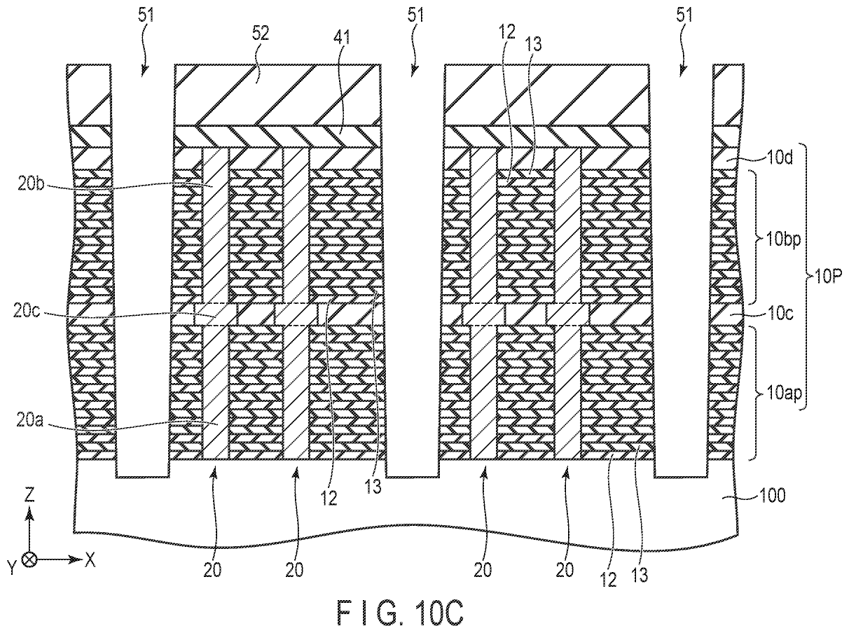

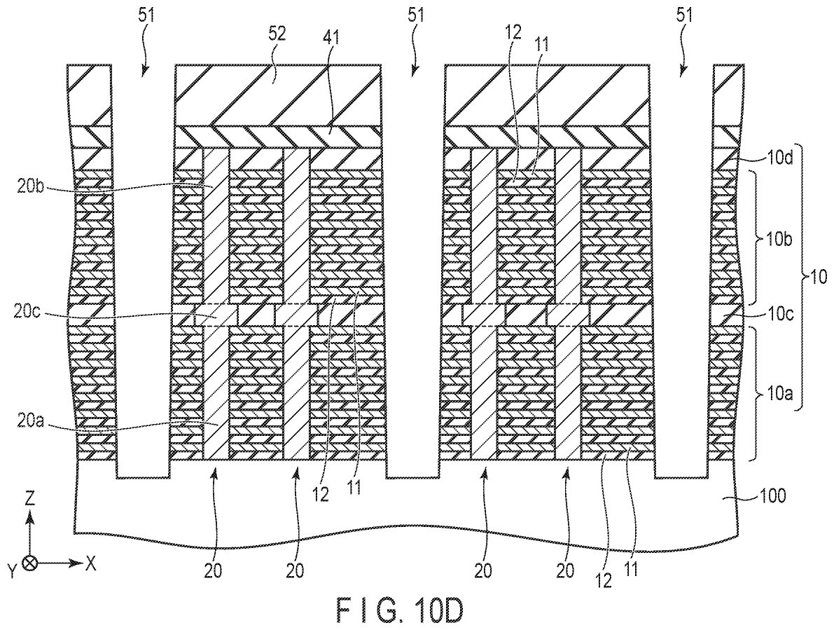

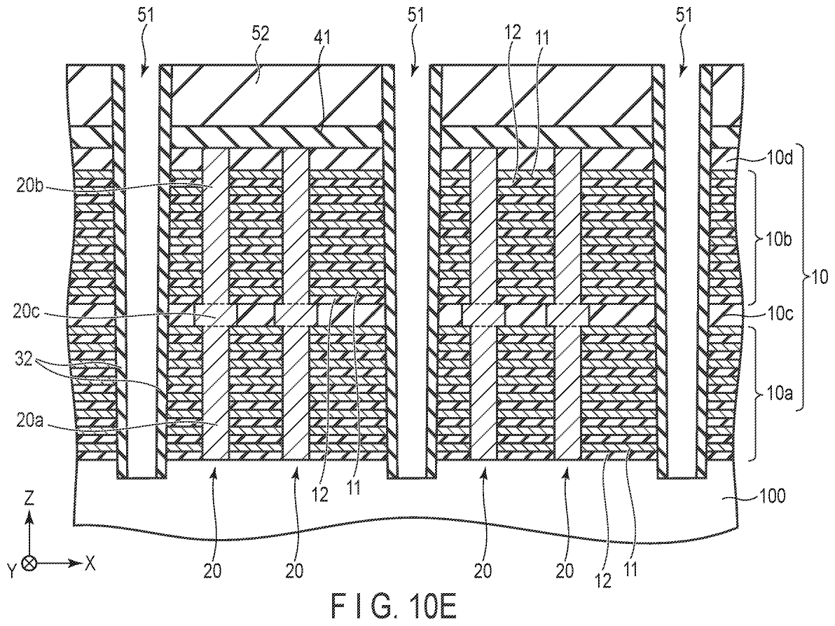

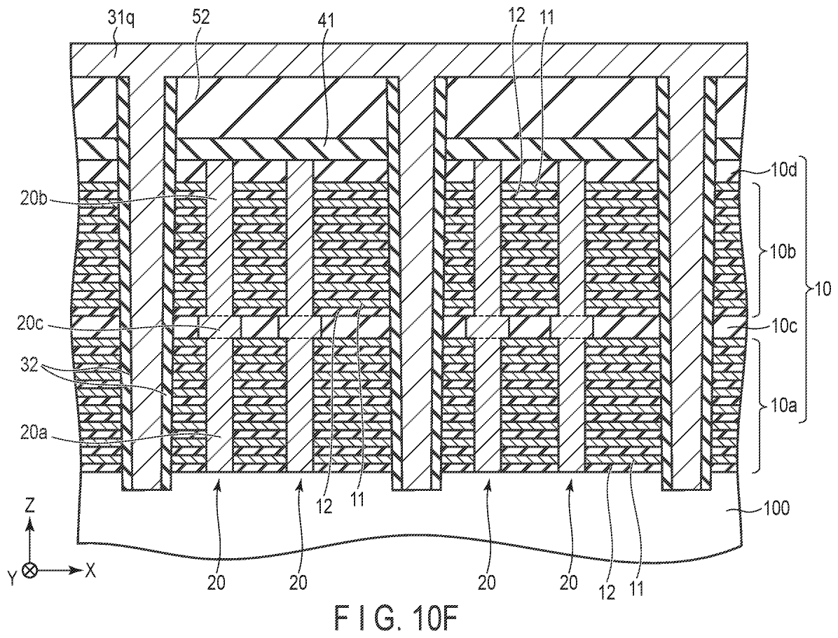

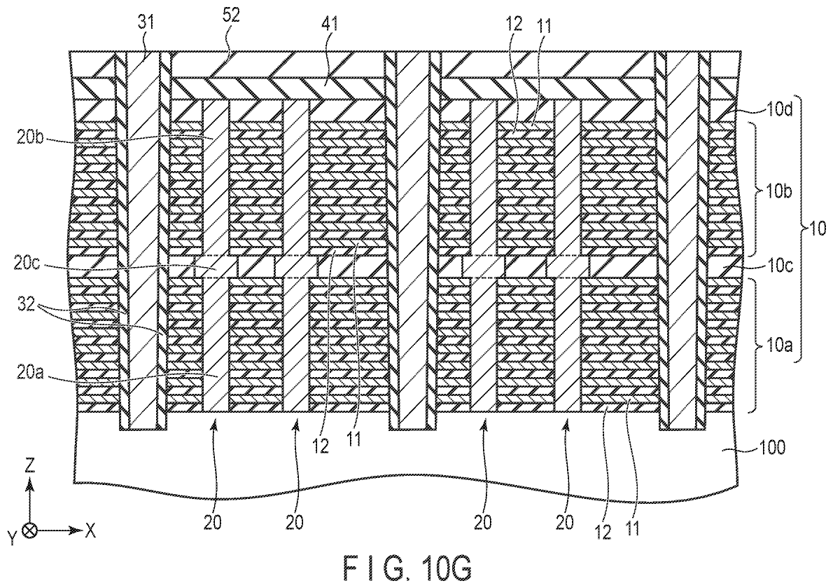

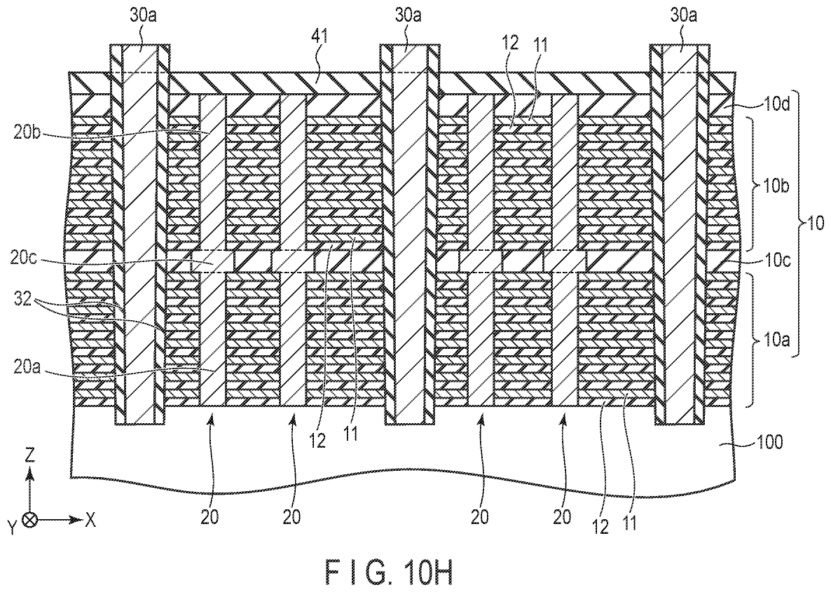

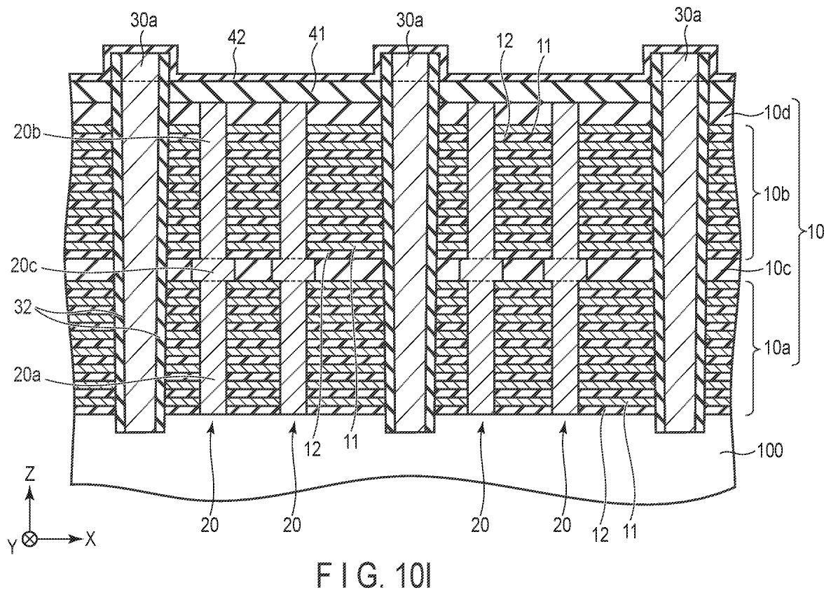

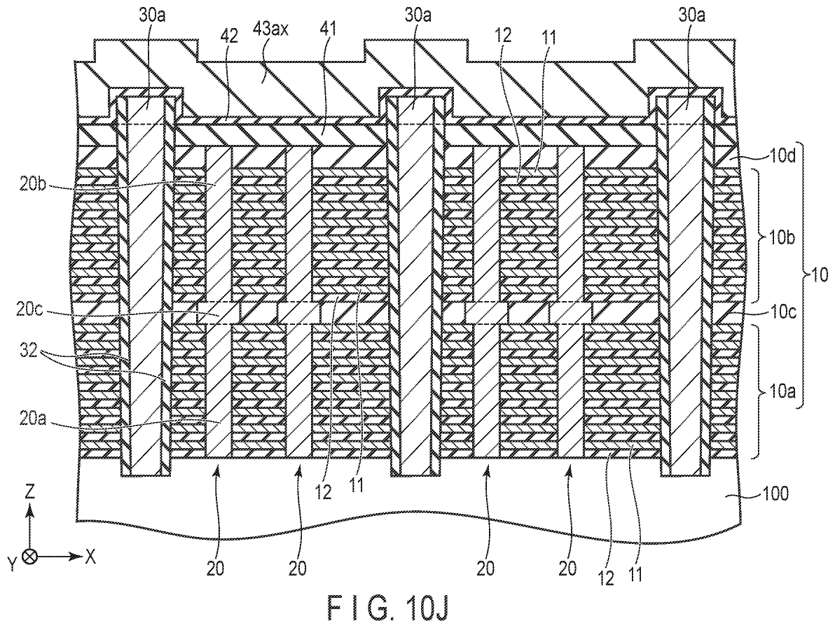

FIG. 1 is a view schematically showing a plane pattern of the basic configuration of a semiconductor memory device (NAND nonvolatile semiconductor memory device) according to a first embodiment. FIG. 2 is a cross-sectional view along line A-A of FIG. 1. It is noted that the X-direction (third direction), Y-direction (second direction), and Z-direction (first direction) shown in each figure are directions intersecting each other. More specifically, the X-direction, Y-direction, and Z-direction are directions orthogonal to each other.

The semiconductor memory device according to this embodiment includes a stacked layer body 10, a plurality of pillar structures 20, a plurality of partition structures 30, and the like.

The stacked layer body 10 is provided on a semiconductor substrate 100, and includes a first stacked portion 10a, second stacked portion 10b, intermediate portion 10c, and upper portion 10d. Each of the first stacked portion 10a and second stacked portion 10b has a structure in which a plurality of conductive layers 11 and a plurality of insulating layers 12 are alternately stacked in the Z-direction. That is, in each of the first stacked portion 10a and second stacked portion 10b, a plurality of conductive layers 11 are stacked to be apart from each other in the Z-direction, and the plurality of conductive layers 11 are electrically insulated from each other with the plurality of insulating layers 12.

The conductive layer 11 is formed of a metallic material such as tungsten (W) or the like, and insulating layer 12 is formed of an insulating material such as silicon oxide or the like. Each of the conductive layer 11 and insulating layer 12 is provided in parallel with the X-Y plane perpendicular to the Z-direction. The conductive layer 11 functions as an electrode layer. More specifically, each conductive layer 11 functions as a word line or selector gate line. The intermediate portion 10c and upper portion 10d are formed of an insulating material such as silicon oxide or the like.

Each of the pillar structures 20 extends through the stacked layer body 10 in the Z-direction and includes a first pillar portion 20a, second pillar portion 20b, and joint portion 20c. Further, each of the pillar structures 20 includes a semiconductor layer extending in the Z-direction and charge storage layer surrounding the side surface of the semiconductor layer. The first pillar portion 20a and second pillar portion 20b are used for the memory cell and select transistor, and the first pillar portion 20a and second pillar portion 20b are joined to each other with the joint portion 20c.

Each of FIG. 3A and FIG. 3B is a cross-sectional view schematically showing the detailed configuration of a memory cell part constituted of the conductive layer 11 and pillar structure 20. FIG. 3A is a cross-sectional view in the direction parallel to the Z-direction, and FIG. 3B is a cross-sectional view in the direction perpendicular to the Z-direction.

The pillar structure 20 includes a semiconductor layer 21, tunnel insulating layer 22, charge storage layer 23, block insulating layer 24, and core insulating layer 25. Each of the semiconductor layer 21, tunnel insulating layer 22, charge storage layer 23, and block insulating layer 24 has a cylindrical shape, and core insulating layer 25 has a columnar shape. More specifically, the semiconductor layer 21 surrounds the side surface of the core insulating layer 25, tunnel insulating layer 22 surrounds the side surface of the semiconductor layer 21, charge storage layer 23 surrounds the side surface of the tunnel insulating layer 22, and block insulating layer 24 surrounds the side surface of the charge storage layer 23. For example, the semiconductor layer 21 is formed of silicon, tunnel insulating layer 22 is formed of silicon oxide, charge storage layer 23 is formed of silicon nitride, block insulating layer 24 is formed of silicon oxide, and core insulating layer 25 is formed of silicon oxide.

The conductive layer 11 surrounding the pillar structure 20 functions as a gate electrode, and a memory cell is constituted of the part of the conductive layer 11 functioning as the gate electrode and part of the pillar structure 20 surrounded with the conductive layer 11.

On the upper layer side and lower layer side of the memory cell part, an upper select transistor part (drain-side select transistor part) and lower select transistor part (source-side select transistor part) both configured to select the memory cell are respectively provided. The basic configuration of each of these select transistor parts is also identical to the configuration of the memory cell part shown in FIG. 3A and FIG. 3B. In the select transistor part, the whole of the tunnel insulating layer 22, charge storage layer 23, and block insulating layer 24 functions as a gate insulating layer.

Each of the partition structures 30 extends in the Z-direction and Y-direction in the stacked layer body 10, and the pillar structures 20 are divided into a plurality of groups in the X-direction by the plurality of partition structures 30. The partition structures 30 are arranged in the X-direction at substantially regular intervals, and the number of columns of the pillar structures 20 arranged between adjacent partition structures 30 is constant. In this embodiment, between the partition structures 30 adjacent to each other, four columns of the pillar structures 20 are arranged. Further, in the region positioned between the partition structures 30 adjacent to each other in the X-direction, the individual conductive layers 11 of the stacked layer body 10 are electrically connected to each other as a common connection.

The partition structure 30 is formed by filling a slit to be used for replace processing to be described later with a predetermined material. The slit is used, in the replace processing, to remove each of sacrificial layers provided between adjacent insulating layers 12 and form the conductive layers 11 in the remaining space after the sacrificial layers are removed.

The partition structure 30 penetrates the stacked layer body 10, and the stacked lay body 10 is divided into a plurality of portions in the X-direction by the partition structures 30. Each of the portions of the stacked layer body 10 divided in the X-direction constitutes, for example, one block functioning as a data erase unit in the semiconductor memory device. The partition structure 30 includes a conductive portion 31 formed of a conductive material, and insulating portion 32 formed of an insulating material such as silicon oxide or the like. The lower end of the conductive portion 31 is connected to the common source region of the semiconductor substrate 100, and upper end of the conductive portion 31 protrudes from the upper end of the stacked layer body 10. In this embodiment, the conductive portion 31 includes a lower portion 31a formed of polysilicon and upper portion 31b formed of a metallic material such as tungsten (W) or the like. The insulating portion 32 is interposed between the conductive portion 31 and stacked layer body 10, and the conductive portion 31 and conductive layers 11 of the stacked layer body 10 are electrically insulated from each other by the insulating portion 32.

On the stacked layer body 10, an insulating layer (first insulating layer) 41 formed of an insulating material such as silicon oxide or the like is provided, and the stacked layer body 10 is covered with the insulating layer 41.

The partition structure 30 includes a protruding portion 30a positioned higher than the top surface of the insulating layer 41. That is, the partition structure 30 includes the protruding portion 30a protruding from the plane defined by the top surface of the insulating layer 41. More specifically, the conductive portion 31 of the partition structure 30 includes the protruding portion 30a.

On the partition structures 30 and insulating layer 41, a covering layer 42 is provided, and stacked layer body 10, insulating layer 41, and the plurality of partition structures 30 are covered with the covering layer 42. The covering layer 42 is provided along the top surface of the insulating layer 41 and along the protruding portions 30a (along the side surfaces and top surfaces of the protruding portions 30a) of the partition structures 30, and is in contact with the top surface of the insulating layer 41 and side surfaces and top surfaces of the protruding portions 30a of the partition structures 30. Accordingly, the height of each of the regions of the covering layer 42 covering the top surfaces of the plurality of partition structures 30 is positioned higher than the height of each of the regions of the covering layer 42 covering the stacked layer body 10 and insulating layer 41. The covering layer 42 is formed of a material different from the material of the insulating layer 41. More specifically, the covering layer 42 is formed of an insulating material such as silicon nitride or the like. The covering layer 42 is used as an etching stopper at the time when contact holes to be described later are formed.

On the covering layer 42, an insulating layer (second insulating layer) 43 is provided, and the covering layer 42 is covered with the insulating layer 43. The insulating layer 43 is formed of a material different from the material of the covering layer 42. More specifically, the insulating layer 43 is formed of an insulating material such as silicon oxide or the like. The insulating layer 43 includes a first layer portion 43a formed by using tetraethyl ortho-silicate (TEOS) as a raw material therefor, second layer portion 43b formed by using silane as a raw material therefor, and third layer portion 43c formed by using TEOS as a raw material therefor. The top surface of the insulating layer 43 is planarized over the region above the plurality of partition structures 30 and above the stacked layer body 10 divided into the plurality of portions by the plurality of partition structures 30.

A contact 50a penetrating the insulating layer 43, covering layer 42, and insulating layer 41 is connected to each of the pillar structures 20, and contact 50b penetrating the insulating layer 43 and covering layer 42 is connected to each of the partition structures 30. The contacts 50a and 50b are formed of a metallic material such as tungsten (W) or the like.

Next, a manufacturing method of the semiconductor memory device according to this embodiment will be described below with reference to the cross-sectional views shown in FIGS. 4A to 4M.

First, as shown in FIG. 4A, a structure including a preparatory stacked layer body 10P, pillar structures 20, and insulating layer (silicon oxide layer) 41 is formed on the semiconductor substrate 100. The preparatory stacked layer body 10P includes a stacked layer portion 10ap, stacked layer portion 10bp, intermediate portion 10c, and upper portion 10d. Each of the stacked layer portions 10ap and 10bp has a structure in which the insulating layers 12 formed of silicon oxide and sacrificial layers 13 formed of silicon nitride are alternately stacked.

Next, as shown in FIG. 4B, the insulating layer 41 and preparatory stacked layer body 10P are subjected to patterning, whereby trenches 51 reaching the semiconductor substrate 100 are formed.

Next, as shown in FIG. 4C, replace processing is carried out. More specifically, the sacrificial layers 13 are subjected to etching through the trenches 51, whereby space is formed between adjacent insulating layers 12. Subsequently, the space is filled with tungsten (W), whereby the stacked layer body 10 is formed.

Next, as shown in FIG. 4D, silicon oxide layers are formed along the inner walls of the trenches 51, whereby the insulating portions 32 are formed. Subsequently, a polysilicon layer 31p is formed inside the trenches 51 and on the insulating layer 41.

Next, as shown in FIG. 4E, the polysilicon layer 31p is subjected to etching by reactive ion etching (RIE), whereby the part of the polysilicon layer 31p on the insulating layer 41 is removed.

Next, as shown in FIG. 4F, a silicon nitride layer is formed on the structure obtained in the step of FIG. 4E as a sacrificial layer 52.

Next, as shown in FIG. 4G, a mask layer 53 is formed on the sacrificial layer 52. The mask layer 53 includes a groove-like opening pattern corresponding to the pattern of the polysilicon layer 31p obtained in the step of FIG. 4E.

Next, as shown in FIG. 4H, the sacrificial layer 52 and polysilicon layer 31p are subjected to etching by RIE by using the pattern of the mask layer 53 as a mask. Thereby, trenches 54 each of which has the top surface of the polysilicon layer 31p as the bottom surface are formed.

Next, as shown in FIG. 4I, a tungsten (W) layer 31q is formed inside the trenches 54 and on the sacrificial layer 52.

Next, as shown in FIG. 4J, the W layer 31q and sacrificial layer 52 are polished by chemical mechanical polishing (CMP). By this CMP step, the W layer 31q on the sacrificial layer 52 and upper portion of the sacrificial layer 52 are removed, and W layer 31q remains on the polysilicon layer 31p. Thereby, the lower portion (polysilicon portion) 31a and upper portion (W portion) 31b of the conductive portion 31 of each of the partition structures 30 are formed.

Next, as shown in FIG. 4K, the sacrificial layer 52 is removed by wet etching. This wet etching of the sacrificial layer 52 is carried out on condition that the etching has selectivity for the insulating layer 41 and partition structures 30. In this embodiment, silicon nitride is used as the material for the sacrificial layer 52, and hence the selective wet etching is carried out by using phosphoric acid. As a result, a part of the conductive portion 31 of each of the partition structures 30 protrudes from the plane defined by the top surface of the insulating layer 41, whereby the protruding portions 30a are formed.

Next, as shown in FIG. 4L, a silicon nitride layer is formed, as the covering layer 42, on the top surface of the insulating layer 41 and on the surface (side surface and top surface) of the protruding portion 30a of each of the conductive portions 31, whereby the stacked layer body 10, insulating layer 41, and protruding portions 30a of the partition structures 30 are covered with the covering layer 42. The covering layer 42 is formed along the top surface of the insulating layer 41 and protruding portions 30a of the partition structures 30, and hence the portions of the covering layer 42 covering the top surfaces of the partition structures 30 are positioned higher than the portions of the covering layer 42 covering the stacked layer body 10 and insulating layer 41.

Next, as shown in FIG. 4M, a silicon oxide layer 43ax for which TEOS is used as the raw material is formed on the covering layer 42.

Next, after the silicon oxide layer 43ax is planarized by CMP, a silicon oxide layer for which silane is used as the raw material and silicon oxide layer for which TEOS is used as the raw material are formed on the silicon oxide layer 43ax as shown in FIG. 2. Thereby, the insulating layer 43 including the first layer portion 43a, second layer portion 43b, and third layer portion 43c is obtained.

Thereafter, contact holes reaching the pillar structures 20 and partition structures 30 are formed. More specifically, first, a hole pattern is formed in the insulating layer 43 by using the covering layer 42 as the etching stopper. Thereafter, the covering layer 42 and insulating layer 41 are etched, whereby contact holes are formed.

Furthermore, the contact holes are filled with a metallic material such as tungsten (W) or the like. Thereby, contacts 50a connected to the pillar structures 20 through the insulating layer 43, covering layer 42, and insulating layer 41, and contacts 50b connected to the partition structures 30 through the insulating layer 43 and covering layer 42 are obtained.

As described above, in this embodiment, the sacrificial layer 52 is formed on the whole surface in the step of FIG. 4F, W layer 31q is formed inside the trenches 54 and on the sacrificial layer 52 in the step of FIG. 4I, and W layer 31q and sacrificial layer 52 are polished by CMP in the step of FIG. 4J. In this embodiment, by forming the W layer 31q on the sacrificial layer 52 in the manner described above, it becomes possible to avoid the problem arising when the W layer 31q is subjected to CMP, and appropriately form the contacts 50a connected to the pillar structures 20 as will be described hereinafter.

Each of FIG. 5A and FIG. 5B is a cross-sectional view schematically showing a state of a vicinity of a boundary region between the memory cell array region M and peripheral circuit region P with respect to a manufacturing method of a comparative example of this embodiment. In this comparative example, no sacrificial layer 52 is formed.

On the left side of each of FIG. 5A and FIG. 5B, the state of the relatively inner side region of the semiconductor wafer is shown. On the right side of each of FIG. 5A and FIG. 5B, the state of the region in the vicinity of the outer circumference of the semiconductor wafer is shown. Further, the region M corresponds to the memory cell array region, and region P corresponds to the peripheral circuit region.

FIG. 5A is a view schematically showing the state (state corresponding to FIG. 4I of this embodiment) before the upper portion (W layer portion) of the conductive portion of the partition structure is formed by CMP.

As shown in FIG. 5A, in the memory cell array region M and peripheral circuit region P, an insulating region 60 formed of silicon oxide is provided, and the stacked layer body 10 and pillar structures 20 are covered with the insulating region 60. The W layer 31q is formed on the insulating region 60. It is noted that on the stacked layer body 10 and pillar structures 20, the insulating region 60 corresponds to the insulating layer 41 of the above-described embodiment.

Although in the relatively inner side region of the semiconductor wafer shown on the left side of FIG. 5A, the height of the insulating region 60 is constant, in the region in the vicinity of the outer circumference of the semiconductor wafer shown on the right side of FIG. 5A, the height of the insulating region 60 becomes lower toward the outer circumference of the semiconductor wafer. This is because it is more difficult, in the region in the vicinity of the outer circumference of the semiconductor wafer, to thickly deposit the silicon oxide to be used for the insulating region 60 as compared with the inner side region.

FIG. 5B is a view schematically showing the state (state corresponding to FIG. 4J of this embodiment) after the upper portion (W layer portion) of the conductive portion of the partition structure is formed by CMP. That is, FIG. 5B shows the state after the W layer 31q shown in FIG. 5A is polished by CMP.

As described above, in the region in the vicinity of the outer circumference of the semiconductor wafer, the height of the insulating region 60 becomes lower toward the outer circumference of the semiconductor wafer. For this reason, in the CMP step to be carried out to remove the W layer 31q on the insulating region 60, in the vicinity of the region in which the height of the insulating region 60 is lower, the thickness of the insulating region 60 covering the stacked layer body 10 and pillar structures 20 tends to become less as compared with the other region. As a result, in the surface of the semiconductor wafer, variations in the thickness of the insulating region 60 occur. In particular, when variations occur in the thickness of the insulating layer 41 on the stacked layer body 10 and pillar structures 20, as will be described hereinafter, there is a possibility of a problem arising when the contact holes are formed.

FIG. 6 is a view showing a problem which can occur when contact holes are formed.

Due to variations occurring in the manufacturing process, the pattern of the contact hole CH is formed misaligned with the pattern of the pillar structure 20 in some cases. As described above, when there are variations in the thickness of the insulating layer 41, in the region in which the thickness of the insulating layer 41 is reduced, at the time of the etching step for forming the contact holes CH, there is a possibility of the contact hole CH reaching the conductive layer 11 of the stacked layer body 10. As a result, there is a possibility of a problem that the contact is connected further to, in addition to the pillar structure 20, the conductive layer 11 occurring.

Each of FIG. 7A and FIG. 7B is a cross-sectional view showing a state of a vicinity of a boundary region between the memory cell array region M and peripheral circuit region P with respect to the manufacturing method of this embodiment.

FIG. 7A is a view schematically showing the state (state corresponding to FIG. 4I of this embodiment) before the upper portion (W layer portion) of the conductive portion of the partition structure is formed by CMP. FIG. 7B is a view schematically showing the state (state corresponding to FIG. 4J of this embodiment) after the upper portion (W layer portion) of the conductive portion of the partition structure is formed by CMP. That is, FIG. 7B shows the state after the W layer 31q shown in FIG. 7A is polished by CMP.

In this embodiment, the sacrificial layer 52 is formed on the insulating region 60. Accordingly, it is possible, in the CMP step for removing the W layer 31q, to protect the insulating region 60 by the sacrificial layer 52. That is, it is possible to protect the insulating layer 41 by the sacrificial layer 52. Thereby, it is possible to prevent the problem that the thickness of the part of the insulating layer 41 on the stacked layer body 10 and pillar structures 20 becomes smaller from occurring. Accordingly, in this embodiment, it is possible to avoid the above-described problem that the contact hole CH reaches the conductive layer 11 of the stacked structure 10, and appropriately form the contact. Further, the sacrificial layer 52 is removed in the step of FIG. 4K, and hence the formation processing of the contact holes is never obstructed by the sacrificial layer 52.

It is noted that even if the insulating region 60 under the sacrificial layer 52 is exposed in the CMP step in, for example, the region in the vicinity of the outer circumference of the semiconductor wafer, it is desirable, in order to prevent the polishing amount from being increased, that CMP be carried out on condition that the polishing rate of the insulating region 60 be lower than the polishing rate of the sacrificial layer 52.

Each of FIG. 8A and FIG. 8B is a cross-sectional view showing a modified example of a state of a vicinity of a boundary region between the memory cell array region M and peripheral circuit region P with respect to the manufacturing method of this embodiment.

Although in the example in each of FIG. 7A and FIG. 7B, the height of the insulating region 60 becomes gradually less toward the outer circumference in the region in the vicinity of the outer circumference of the semiconductor wafer, in this modified example, a step is formed in the insulating region 60 in the region in the vicinity of the outer circumference of the semiconductor wafer. Even when the insulating region 60 is formed in such a state, it is possible to obtain the advantageous effect identical to the above-described advantageous effect.

### Second Embodiment

Next, a second embodiment will be described below. It is noted that the fundamental items are identical to the first embodiment, and descriptions of the items described in the first embodiment are omitted.

FIG. 9 is a cross-sectional view schematically showing the basic configuration of a semiconductor memory device (NAND nonvolatile semiconductor memory device) according to this embodiment. It is noted that the plane pattern is identical to FIG. 1 of the first embodiment, and the cross section along line A-A of FIG. 1 corresponds to FIG. 9.

In this embodiment, the structure of the partition structure 30 differs from the first embodiment. That is, although in the first embodiment, the conductive portion 31 of the partition structure 30 is constituted of the lower portion 31a formed of polysilicon and upper portion 31b formed of a metallic material such as tungsten (W) or the like, in this embodiment, the whole of the conductive portion 31 is formed of a metallic material such as tungsten (W) or the like. Further, in this embodiment, the insulating portion 32 extends to a height substantially equal to the upper end (top surface) of the conductive portion 31. Accordingly, in this embodiment, the conductive portion 31 and insulating portion 32 of the partition structure 30 include the protruding portion 30a. The side surface of the conductive portion 31 is surrounded with the insulating portion 32.

In this embodiment too, as in the case of the first embodiment, the covering layer 42 is provided on the partition structures 30 and insulating layer 41 and, the stacked layer body 10, insulating layer 41, and the plurality of partition structures 30 are covered with the covering layer 42. In this embodiment too, as in the case of the first embodiment, the covering layer 42 is provided along the top surface of the insulating layer 41 and along the protruding portions 30a of the partition structures 30 (along the side surfaces and top surfaces of the protruding portions 30a), and is in contact with the top surface of the insulating layer 41 and protruding portions 30a (side surfaces and top surfaces of the protruding portions 30a) of the partition structures 30. Accordingly, as in the case of the first embodiment, the height of each of the regions of the covering layer 42 covering the top surfaces of the plurality of partition structures 30 is positioned higher than the height of each of the regions of the covering layer 42 covering the stacked layer body 10 and insulating layer 41. The material of the covering layer 42 and function thereof are identical to the first embodiment.

Next, a manufacturing method of the semiconductor memory device according to this embodiment will be described below with reference to the cross-sectional views shown in FIGS. 10A to 10J.

First, as shown in FIG. 10A, in the same manner as the step of FIG. 4A of the first embodiment, a structure including a preparatory stacked layer body 10p, pillar structures 20, and insulating layer (silicon oxide layer) 41 is formed on the semiconductor substrate 100.

Next, as shown in FIG. 10B, the sacrificial layer 52 is formed on the insulating layer 41. It is noted that although in the first embodiment, the silicon nitride has been used for each of the sacrificial layer 13 and sacrificial layer 52, in this embodiment, in order to prevent the sacrificial layer 52 from being removed when the sacrificial layers 13 are removed in the replace processing to be described later, a material having etching resistance to the etchant of the sacrificial layer 13 is used for the sacrificial layer 52.

Next, as shown in FIG. 10C, the sacrificial layer 52, insulating layer 41, and preparatory stacked layer body 10P are subjected to etching, whereby the trenches 51 reaching the semiconductor substrate 100 are formed.

Next, as shown in FIG. 10D, replace processing is carried out. More specifically, the sacrificial layers 13 are subjected to etching through the trenches 51, whereby spaces are formed between adjacent insulating layers 12. Subsequently, the spaces are filled with tungsten (W), whereby the stacked layer body 10 is formed.

Next, as shown in FIG. 10E, silicon oxide layers are formed along the inner walls of the trenches 51, whereby the insulating portions 32 are formed.

Next, as shown in FIG. 10F, a tungsten (W) layer 31q is formed inside the trenches 51 in which the insulating portions 32 are formed and on the sacrificial layer 52.

Next, as shown in FIG. 10G, the W layer 31q, insulating portions 32, and sacrificial layer 52 are polished by CMP. By this CMP step, the W layer 31q on the sacrificial layer 52 and upper portion of the sacrificial layer 52 are removed. Thereby, the partition structures 30 each including the conductive portions 31 and insulating portions 32 are formed.

Next, as shown in FIG. 10H, the sacrificial layer 52 is removed by wet etching. This wet etching of the sacrificial layer 52 is carried out on condition that the etching has selectivity for the insulating layer 41 and partition structures 30. As a result, a part of the conductive portion 31 and a part of the insulating portion 32 included in each of the partition structures 30 protrude from the plane defined by the top surface of the insulating layer 41, whereby the protruding portions 30a are formed.

Next, as shown in FIG. 10I, a silicon nitride layer is formed, as the covering layer 42, on the top surface of the insulating layer 41 and on the surface (side surface and top surface) of the protruding portion 30a of each of the partition structures 30. Thereby, the stacked layer body 10, insulating layer 41, and partition structures 30 are covered with the covering layer 42. As in the case of the first embodiment, in this embodiment too, the covering layer 42 is formed along the top surface of the insulating layer 41 and protruding portions 30a of the partition structures 30, and hence the portions of the covering layer 42 covering the top surfaces of the partition structures 30 are positioned higher than the portions of the covering layer 42 covering the stacked layer body 10 and insulating layer 41.

Next, as shown in FIG. 10J, a silicon oxide layer 43ax for which TEOS is used as the raw material is formed on the covering layer 42.

Next, after the silicon oxide layer 43ax is planarized by CMP, a silicon oxide layer for which silane is used as the raw material and silicon oxide layer for which TEOS is used as the raw material are formed on the silicon oxide layer 43ax as shown in FIG. 9. Thereby, the insulating layer 43 including the first layer portion 43a, second layer portion 43b, and third layer portion 43c is obtained.

Thereafter, contact holes reaching the pillar structures 20 and partition structures 30 are formed. More specifically, first, a hole pattern is formed in the insulating layer 43 by using the covering layer 42 as the etching stopper. Thereafter, the covering layer 42 and insulating layer 41 are etched, whereby contact holes are formed.

Furthermore, the contact holes are filled with a metallic material such as tungsten (W) or the like. Thereby, contacts 50a connected to the pillar structures 20 through the insulating layer 43, covering layer 42, and insulating layer 41, and contacts 50b connected to the partition structures 30 through the insulating layer 43 and covering layer 42 are obtained.

In this embodiment too, as in the case of the first embodiment, the state at the time when the W layer 31q is formed in the step of FIG. 10F is identical to the state shown in FIG. 7A or FIG. 8A of the first embodiment, and state at the time when the W layer 31q and sacrificial layer 52 are polished by CMP in the step of FIG. 10G is identical to the state shown in FIG. 7B or FIG. 8B of the first embodiment. Accordingly, as in the case of the first embodiment, it becomes possible to avoid the problem occurring when the W layer 31q is subjected to CMP, and appropriately form the contacts 50a connected to the pillar structures 20.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked layer body in which a plurality of conductive layers are stacked to be apart from each other in a first direction;
a plurality of pillar structures each of which includes a semiconductor layer extending in the first direction through the stacked layer body;
a plurality of partition structures each of which extends in the first direction and a second direction intersecting the first direction in the stacked layer body, and which divide the stacked layer body into a plurality of portions in a third direction intersecting the first and second directions; and
a covering layer which covers the stacked layer body and the plurality of partition structures, and in which a height in each of regions covering top surfaces of the plurality of partition structures is positioned higher than a height in each of regions covering the portions of the stacked layer body.

2. The device of claim 1, wherein
the covering layer is formed of silicon nitride.

3. The device of claim 1, further comprising a first insulating layer covering the stacked layer body, covered with the covering layer, and formed of a material different from a material of the covering layer.

4. The device of claim 3, wherein
the first insulating layer is formed of silicon oxide.

5. The device of claim 3, wherein
each of the partition structures includes a protruding portion protruding from a plane defined by a top surface of the first insulating layer, and
the covering layer is provided along the top surface of the first insulating layer and along the protruding portion of each of the partition structures.

6. The device of claim 5, wherein
the covering layer is in contact with the top surface of the first insulating layer and the protruding portion.

7. The device of claim 5, wherein
the protruding portion is formed of a conductive portion.

8. The device of claim 5, wherein
the protruding portion is formed of a conductive portion and an insulating portion surrounding a side surface of the conductive portion.

9. The device of claim 3, further comprising a second insulating layer covering the covering layer and formed of a material different from the material of the covering layer.

10. The device of claim 9, wherein
the second insulating layer is formed of silicon oxide.

11. The device of claim 9, wherein
a top surface of the second insulating layer is planarized over a region above the plurality of partition structures and above the portions of the stacked layer body.

12. The device of claim 9, wherein
the stacked layer body includes a third insulating layer arranged between an uppermost one of the plurality of conductive layers and the first insulating layer, and the first insulating layer and the third insulating layer are formed of silicon oxide.

13. The device of claim 9, further comprising a plurality of contacts penetrating the second insulating layer, the covering layer and the first insulating layer and connected to the plurality of pillar structures.

14. The device of claim 1, wherein
the plurality of partition structures divide the plurality of pillar structures into a plurality of groups in the third direction.

15. The device of claim 1, wherein
the plurality of partition structures are arranged in the third direction at substantially regular intervals.

16. The device of claim 3, wherein
each of the plurality of partition structures penetrates the stacked layer body and the first insulating layer.

17. The device of claim 1, wherein
each of the plurality of partition structures includes a conductive portion.

18. The device of claim 17, further comprising a semiconductor portion on which the stacked layer body is provided, wherein
the conductive portion is connected to the semiconductor portion.

19. The device of claim 17, wherein
each of the plurality of partition structures further includes an insulating portion interposed between the stacked layer body and the conductive portion.

20. The device of claim 1, wherein
the stacked layer body has a structure in which the plurality of conductive layers and a plurality of insulating layers are alternately stacked in the first direction.
